(19) United States
(12) Patent Application Publication
(10) Pub. No.: US 2011/0242750 A1
(43) Pub. Date: Oct. 6, 2011

(54) ACCESSIBLE DISPLAY IN DEVICE WITH CLOSED LID

(76) Inventor: Nicholas W. Oakley, Portland, OR (US)

(21) Appl. No.: 12/752,733

(22) Filed: Apr. 1, 2010

(51) Int. Cl. H05K 7/00

(52) U.S. Cl. 361/679.27

(57) ABSTRACT

Disclosed are electronic devices whereby a main display may be used even when the device is in a closed-lid position. In some embodiments, a window (display portion opening) may be provided in the device housing so that a portion of the display may be viewed when the lid is closed.

### TECHNICAL FILED

The present invention relates generally to electronic devices with closed lids and in particular, to a device whose display may be accessed through a closed lid.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a perspective view of an electronic device in an open lid position in accordance with some embodiments.

FIG. 2 shows the device of FIG. 1 in a partially closed lid portion in accordance with some embodiments.

FIG. 3 shows the device of FIGS. 1 and 2 in a closed lid position in accordance with some embodiments.

FIG. 4 is a block diagram of a computing system suitable for the device of FIGS. 1-3 in accordance with some embodiments.

FIG. 5A shows a display for the device of FIGS. 1-3 in an open lid mode.

FIG. 5B shows the display from FIG. 5A but when the device is in a closed lid mode.

### DETAILED DESCRIPTION

Many electronic devices use a so-called clam shell configuration whereby the device, in an “open lid” position, exposes a primary display, as well as user input mechanisms such as keypads, touch pads, etc. On the other hand, when the device is in a “closed lid” (folded) position, the display and user input mechanisms are typically in a protected, inaccessible (not viewable) position, and the device is also normally powered off. This is the case, for example, with many so-called notebook and netbook portable computers, as well as with some cellular phone designs.

At the same time, for many users, it may be convenient to be able to quickly and efficiently use their device in a closed-lid position, without having to open it up and power it on in a normal manner. Accordingly, some contemporary designs include an additional (auxiliary) smaller display, usually positioned on the outside of the device when closed, so that the user does not have to open the lid to access information in the device such as appointment information, emails, instant-messages, etc. Unfortunately, such additional displays add costs that may make them less competitive. In addition, for these secondary, closed-lid displays, it may also be desired to provide a touch screen in cooperation with the display, which adds even more expense.

Thus, in some embodiments, disclosed are electronic devices with clam shell designs whereby the main display may be used even when the device is in a closed-lid position. In some embodiments, a window (display portion opening) may be provided in the device housing so that a portion of the display may be viewed when the lid is closed.

In some embodiments, the window may comprise a touch pad made of a transparent material such that the user can interact with the displayed portion using the touch pad on its back side during a closed lid operational mode, as well as be able to use it from the top side during a normal, open lid mode. Thus, the user may be able to conveniently see information from the device when the lid is closed, e.g., while carrying it, or any other time when it is desired not to completely power up the system.

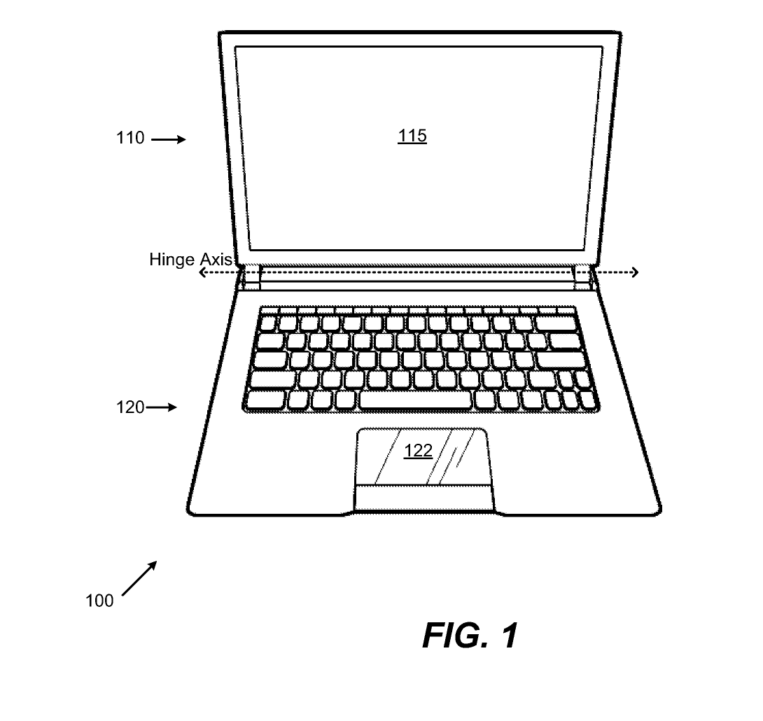

FIGS. 1-3 show an electronic device 100 (a notebook computer in this embodiment) with a display portion that is accessible during a closed lid mode. Portable computer 100 is generally formed from first and second housing sections 110, 120, respectively, rotatably coupled together at a hinge axis. The first section, an upper clam shell section in this embodiment, includes a display 115. Display screen 115 may be selected from one or more readily-available display technologies, for example, liquid crystal displays (LCDs), cathode ray tubes (CRTs), plasma displays, surface-conduction electron-emitter displays (SEDs) and organic light-emitting diode (OLED). Of course, alternative display technologies and/or after-developed display technologies may be used.

Some manufacturers have recently been using OLED materials. OLED is a technology developed by the Eastman Kodak Company of Rochester, N.Y. They are thin film materials which emit light when excited by electric current. Since OLEDs emit light of different colors, they can be used to make displays without the need for a separate back light source. OLED displays are usually lightweight and may operate efficiently at relatively low voltages, thus consuming less power from the system. For some embodiments, the display 115 may be formed from an OLED display or a display that includes picture elements (pixels) having brightness individually controllable.

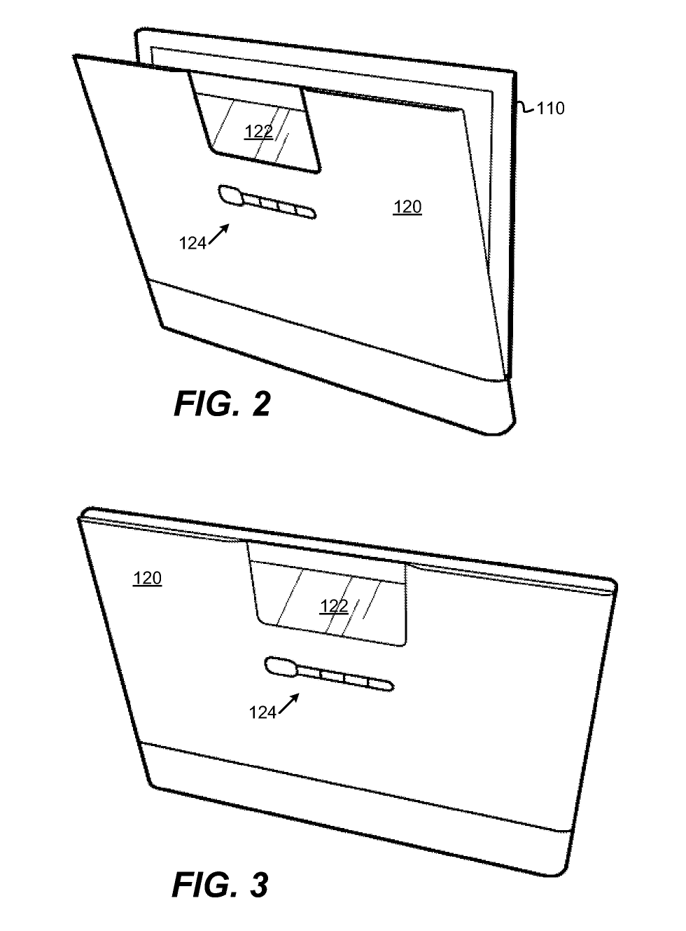

The second section 120, a lower clam shell section in this embodiment, includes a closed lid display opening, occupied in this embodiment with a transparent, two-sided touch pad 122. As seen in FIGS. 2 and 3, the lower section may also include one or more input control keys (or buttons) 124 for controlling and/or activating the device in the closed lid mode. The physical design of the lower section 120 incorporates the display portion opening, which may approximately be the size of the touch pad 122. In the depicted embodiment, the opening is approximately 100 mM×80 mM, but an opening for viewing a display portion during a closed lid mode could be of any suitable shape or size depending on particular design considerations.

In some embodiments, the touch pad is double-sided in that it allows for touch control on both sides. when the lid is open and the user is in front of the display, the top side of the touch pad may be used for interaction with the computer. On the other hand, when the lid is closed, a user may use the back (or under) side of the touch pad for interacting with the portion of the display that is accessible through the transparent touch pad.

The touch pad (or touch screen), when double-sided, may be implemented with any suitable transparent touch pad technology allowing for touch control on both sides. For example, first and second transparent touch pad sheets may be coupled together, back-to-back, so that their touch sensitive sides are facing outward on either side. They may include a sheet of transparent material such as glass or plastic sandwiched between the touch pad sheets. On either or both sides of the touch screen, a touch screen may be configured to generate input/output (I/O) signals in response to tactile pressure at certain locations within the touch screen (e.g. touching a particular portion of the touch screen using a stylus, finger, etc.). Alternatively, a touch screen may comprise a clear (e.g., glass or plastic) panel having a touch responsive surface. A touch screen may be selected from among a plurality of readily available touch screen technologies, for example, pressure-sensitive (resistive), acoustically-sensitive (surface wave), photo-sensitive (infrared), and electrically-sensitive (e.g., capacitive) touch screens.

Note that while embodiments have been described with display openings having transparent, double-sided touch screens, other embodiments could also be employed. In some embodiments, a touch screen with touch control on only one side could be used, or a touch screen could be omitted altogether. For example, the opening could be empty, or it could include a clear material (e.g., plastic) to cover the opening and seal out dirt. Alternatively, a plastic or glass lens could cover the opening. In other embodiments, a plastic privacy filter could cover the opening such that the display would appear dark when viewed from an angle. In another embodiment, an opaque sliding cover could be used to protect the opening, providing both privacy and physical protection against scratches or damage.

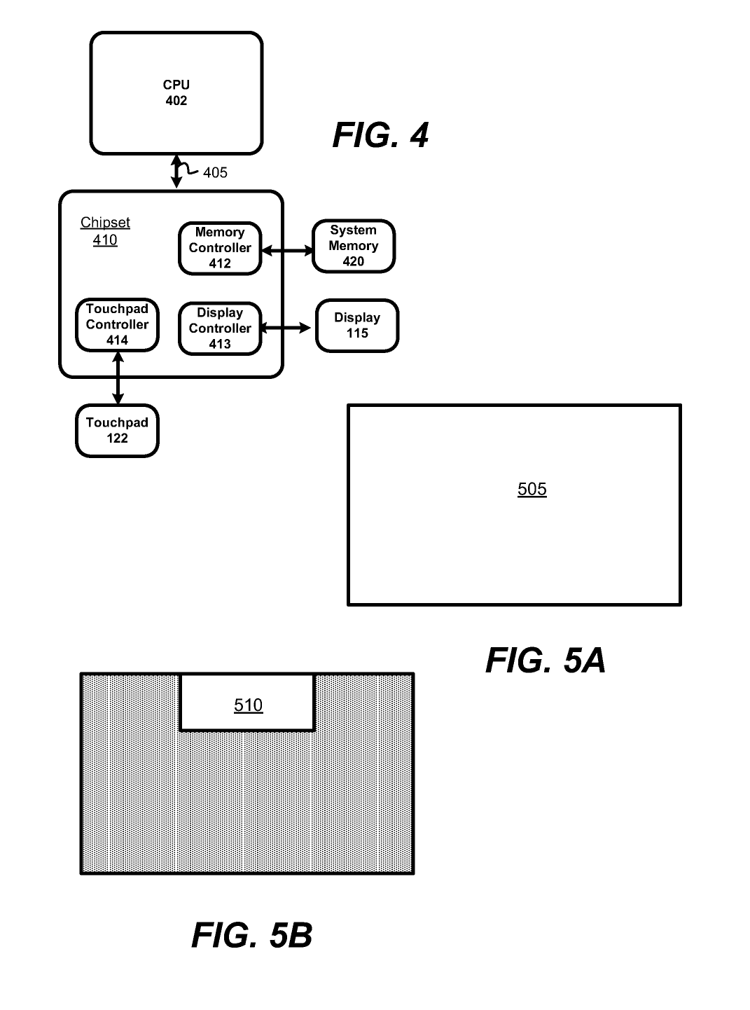

FIG. 4 is a block diagram illustrating an example of a computer system that may be used in accordance with an embodiment of the invention. The computer system may include a central processing unit (CPU) or processor 402 and may receive its power from an electrical outlet or a battery. The CPU 402 may be coupled to a chipset 410 via a link 405. The CPU 402 may be manufactured by, for example, Intel Corporation of Santa Clara, Calif., although it may also be manufactured by other companies. The link 405 generally represents any communication link such as one or more point-to-point links comprising multiple parallel lanes and/or one or more busses.

Chipset 410 may include a memory controller 412. The memory controller 412 may be coupled to system memory 420 (e.g., random access memory (RAM), read-only memory (ROM), etc.). The system memory 420 may store data and sequences of instructions that are executed by the CPU 402 or any other processing devices included in the computer system. For example, in addition to the CPU 402, the computer system may include a secondary CPU or controller (not shown).

The chipset 410 may include a display controller 413. The display 115 may be coupled to the display controller 413. The display controller 413 may be separate from a part of or implemented with a graphics processing unit (GPX). As discussed more below, the display controller 413 controls display 115 and among other things, may control it differently for several different operation modes. In some embodiments, it may control it to consume less power when the lid is closed and limit display to a portion of the display 115 that is viewable through the display portion opening.

The chipset 410 may also include a touch pad controller 414 coupled to the touch pad 122. The touch pad controller 414 may be separate from or part of an input/output (I/O) control section and serves to interpret touch stimulus onto the touch screen 122, e.g., on one or both sides of the screen and control the computer based on the interpreted input stimulus. The computer system may include other peripheral input/output devices including an audio device and a disk drive that may also be coupled to the chipset and/or CPU.

For wireless communication, an antenna (not shown) may also be coupled to a wireless interface, which also may be part of the chipset. Although not shown, other devices (e.g., keyboard, mouse, etc.) may also be connected to the chipset. The computer system may use a direct current (DC) power source such as, for example, a battery. Alternatively, it may use an alternating current (AC) power source by, for example, plugging into an electrical connector. The computer system may consume the most power when it is in a normal power mode. It may consume less power when it is in a low power mode (e.g., suspend or standby mode), or closed lid display mode, which may be important when a DC power source is used.

It should be appreciated that for convenience, separate CPU and chipset blocks are shown. However, in actual implementations, the CPU and Chipset functions may be implemented in a single chip (such as with an SOC implementation) or with several chips, and the different functions may be performed wholly by the separate functional blocks or in cooperation with other blocks within either or both of the CPU and chipset functional units. For example, in some implementations, memory and/or the display may be coupled directly to the CPU. The CPU and chipset may include various additional ports and/or links for communication with depicted blocks or other blocks not shown.

With reference to FIGS. 5A and 5B, a full display and a partial display, closed lid, mode are shown. FIG. 5A shows the computer in a full viewing area 505 mode, while FIG. 5B shows the display with only a partial viewing area 510 for a reduced power, closed lid mode.

In some embodiments, during a closed lid mode, only a portion of the display 115 is turned-on (e.g., such as for OLED technology) or backlit (such as for LED or LCD implementations).

The reduced display area 510 may be of any suitable shape, size and implementation, although it should accommodate viewing through the display portion opening when the lid is closed. For example, the display 115 may have pixels with brightness that may be individually controlled. For one embodiment, the display controller 413 may include logic to limit displaying information to only within the display area 510 when the lid is closed. The information (or display content) may be limited or shrunk to fit in a smaller display area using different techniques. For one embodiment, display content may be passed through a scaling logic in the display controller 413 that transforms the pixels by multiplying with a fraction and discarding any fractional values. For example, when display controller 413 reduces a display area from a full size to one that is one sixteenth of the full size, the rows and columns may each be multiplied by 0.25 and the row and column locations may be transferred to appropriate row and columns in the reduced size access area.

For another embodiment, the transformation may be performed in software using, for example, a video driver and operating system (OS), such that the display content may be reduced with little loss of readability. For example, the OS may have a ‘simple’ mode where a lot of the graphic details on icons, tool bars etc may be eliminated to save space. The OS may have an entirely new user-interface mode that can be switched to accommodate smaller display areas as those typically used in cell phones, personal digital assistants (PDA), etc. The interface protocol between the display controller 413 and the display 115 (e.g., a Low Voltage Differential Signaling (LVDS) interface) may also be enhanced to support such modes. For example, the display controller 413 may send only data for a fraction of the screen and the display 115 may fill in the rest of the areas with black (pixels turned off). Power may be saved on the interface also by not having to send a lot of black pixels. The new interface may default all pixels to black unless data is sent for that pixel.

The pixels associated with the display area 510 may be configured to emit light or be turned on, and the pixels associated with the remaining area may be configured to not emit light or be turned off.

In a typical embodiment, the display portion 510 image may be rendered in a normal orientation. In another embodiment, the image may be rendered upside-down on the display using standard software algorithms to flip the image, such that it will be right-side up and oriented properly when the user has the display oriented upside down while looking through the display portion opening from the computer backside. In another embodiment, the image may be rotated clockwise/counterclockwise on the LCD using standard software algorithms. In some embodiments, a sensor switch indicates whether the lid is closed, and may impact the mode in which alerts are rendered.

In some embodiments, an indicator (e.g., LED) may be part of panel 124 to alert a user, e.g., when a message is available for viewing. In some embodiments, one or more buttons may allow a user to view messages and/or navigate through them in the closed lid mode. In some embodiments, speaker(s) may be disposed on one or more edges of the computing device such that they can be easily heard both when the lid is open and when it is closed.

In the preceding description, numerous specific details have been set forth. However, it is understood that embodiments of the invention may be practiced without these specific details. In other instances, well-known circuits, structures and techniques may have not been shown in detail in order not to obscure an understanding of the description. With this in mind, references to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

For example, while clam shell type hinged devices have been mainly discussed, other configurations may incorporate aspects of the invention. For example, display portion openings could be incorporated into cellular phones with slidable first and second sections, whereby an open lid mode occurs when the sections are slid apart and a closed lid mode may occur when they are slid together in a closed position.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

It should also be appreciated that in some of the drawings, signal conductor lines are represented with lines. Some may be thicker, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS, for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. An electronic device, comprising:
a first section having a display; and
a second section mechanically coupled to the first section, the second section having a display portion opening to allow for a portion of the display to be viewed when the first and second sections are in a closed position.

2. The electronic device of claim 1, in which the first and second sections define a portable personal computer.

3. The electronic device of claim 2, in which the portable personal computer is a notebook computer.

4. The electronic device of claim 1, in which the first and second sections are part of a cellular phone.

5. The electronic device of claim 1, in which the first and second sections are hinged together.

6. The electronic device of claim 1, in which the display portion opening includes a transparent touch screen.

7. The electronic device of claim 6, in which the touch screen has top and back sides and is touch control operative on both the top and back sides.

8. The electronic device of claim 7, in which the touch screen comprises first and second transparent touch pad sheets coupled together in a back-to-back configuration.

9. The electronic device of claim 8, in which the first and second touch pad sheets are sandwiched about an interposed sheet of transparent material.

10. The electronic device of claim 9, in which the interposed sheet of transparent material comprises glass.

11. An apparatus, comprising:
an upper section including a display; and
a lower section coupled to the upper section in a clam shell configuration, the lower section including a display portion opening, wherein the lower and upper section when open allow for the display to be viewed and when closed, allow for only a portion of the display to be viewed through the display portion opening.

12. The apparatus of claim 11, in which the display portion opening includes a transparent touch screen.

13. The apparatus of claim 12, in which the touch screen has top and back sides and is touch control operative on both the top and back sides.

14. The apparatus of claim 13, in which the touch screen comprises first and second transparent touch pad sheets coupled together in a back-to-back configuration.

15. The apparatus of claim 14, in which the first and second touch pad sheets are sandwiched about an interposed sheet of transparent material.

16. An apparatus, comprising:
a housing having a display that cannot be seen, when the housing is in a closed mode, except through a display portion opening.

17. The apparatus of claim 16, in which the display portion opening includes a transparent touch screen.

18. The apparatus of claim 17, in which the touch screen has top and back sides and is touch control operative on both the top and back sides.

19. The apparatus of claim 18, in which the touch screen comprises first and second transparent touch pad sheets coupled together in a back-to-back configuration.
